(19) United States
(12) Patent Application Publication
(10) Pub. No.: US 2014/0106604 A1
(43) Pub. Date: Apr. 17, 2014

(54) AIRFLOW GUIDE MEMBER AND CARD SOCKET ASSEMBLY WITH AIRFLOW GUIDE MEMBER

(71) Applicant: HON HAI PRECISION INDUSTRY CO., LTD., New Taipei (TW)

(72) Inventors: CHIN-HUI CHEN, New Taipei (TW); ZHENG-HENG SUN, New Taipei (TW); CHENG-HSIU YANG, New Taipei (TW)

(73) Assignee: HON HAI PRECISION INDUSTRY CO., LTD., New Taipei (TW)

(21) Appl. No.: 13/743,347

(22) Filed: Jan. 17, 2013

(30) Foreign Application Priority Data
Oct. 11, 2012 (TW) 101137547

(51) Int. Cl. H05K 7/20

(52) U.S. Cl. CPC H05K 7/20145
USPC 439/485; 137/343

(57) ABSTRACT

A card socket assembly includes a card socket and a non-conductive airflow guide member. The card socket includes a main body defining a slot, and two latches rotatably connected to opposite ends of the main body. The airflow guide member includes a main plate and an airflow guide plate. A bottom of the main plate is inserted into the slot of the card socket. Two notches are defined in a first end and a second end of the main plate opposite to the first end, to receive the latches. The airflow guide plate is formed on the first end of the main plate, and includes an airflow guide portion slanted relative to the main plate, to guide airflow away from the card socket.

### BACKGROUND

1. Technical Field

The present disclosure relates to a card socket assembly having an airflow guide member.

2. Description of Related Art

Many electronic components may be mounted in an electronic device including card sockets. Layout of the components and airflow for heat dissipation will be according to all the sockets being in use. However, if some card sockets are not use, airflow may be different than planned for, which can result in reduced airflow where it is most needed and thus overheating of components.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a card socket assembly.

FIGS. 2 and 3 are assembled, isometric views of the card socket assembly of FIG. 1 in different states.

FIG. 4 is similar to FIG. 2, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

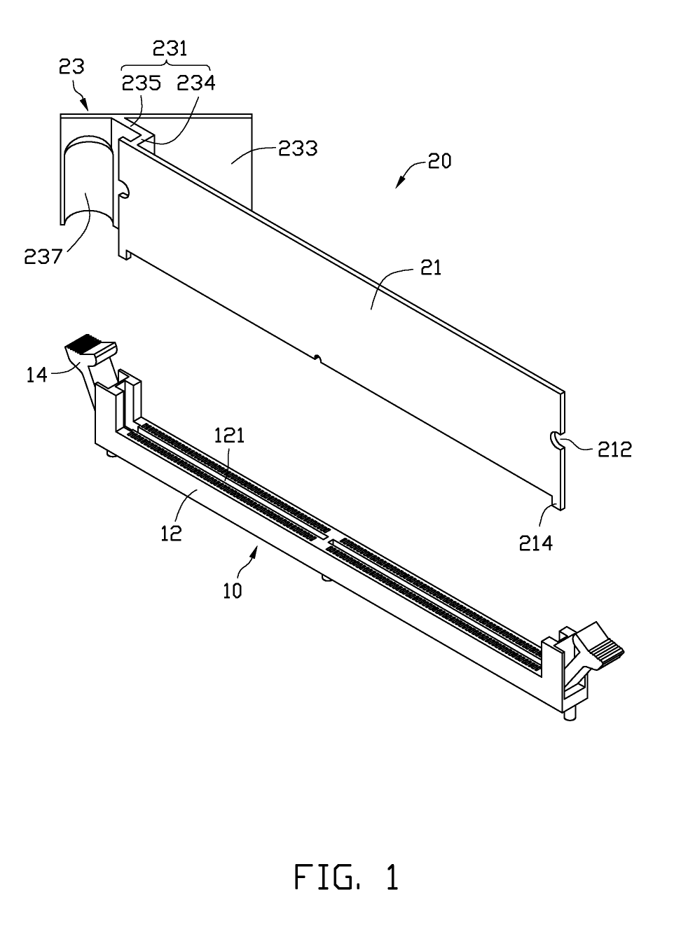

FIG. 1 shows an exemplary embodiment of a card socket assembly. The card socket assembly includes a card socket 10 and an airflow guide member 20.

The card socket 10 includes an elongated main body 12 and two latches 14 rotatably connected to opposite ends of the main body 12. A slot 121 is defined in the top of the main body 12.

The airflow guide member 20 includes a substantially rectangular main plate 21 and an airflow guide plate 23 formed on a first end of the main plate 21. A notch 212 is defined in each of the first end and a second end of the main plate 21 opposite to the first end. Two feet 214 protrude down from opposite ends of the bottom of the main plate 21. The airflow guide plate 23 includes a substantially L-shaped connecting portion 231 connected to a first side of the main plate 21 adjacent to the first end, and a substantially rectangular airflow guide portion 233 connected to the connecting portion 231. The connecting portion 231 includes a first plate 234 perpendicularly connected to the first side of the main plate 21, and a second plate 235 perpendicularly extending out of the first end of the main plate 21 from a distal end of the first plate 234. A middle of a side of the airflow guide portion 233 is connected to a distal end of the second plate 235 away from the first plate 234. The airflow guide portion 233 is slanted relative to the second plate 235 and the main plate 21, to form an acute angle between the airflow guide portion 233 and the first side of the main plate 21, and to form an obtuse angle between the airflow guide portion 233 and a second side of the main plate 21 opposite to the first side. An arc-shaped recess 237 is defined in a section of the side of the airflow guide portion 233 facing the second side of the main plate 21.

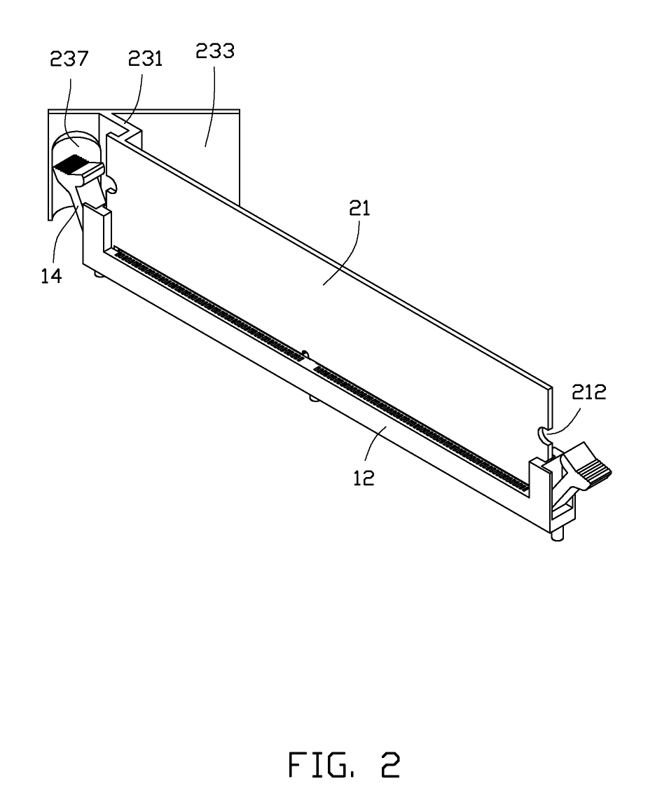

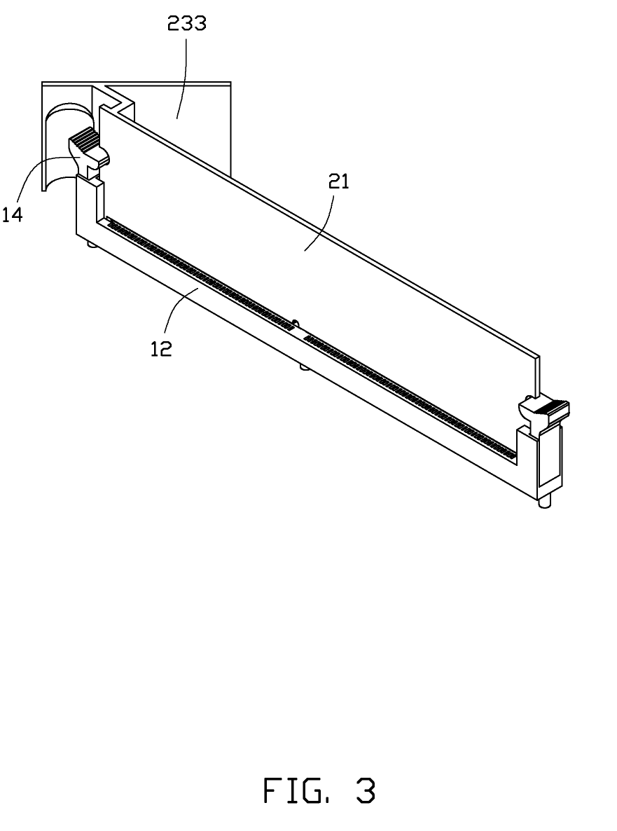

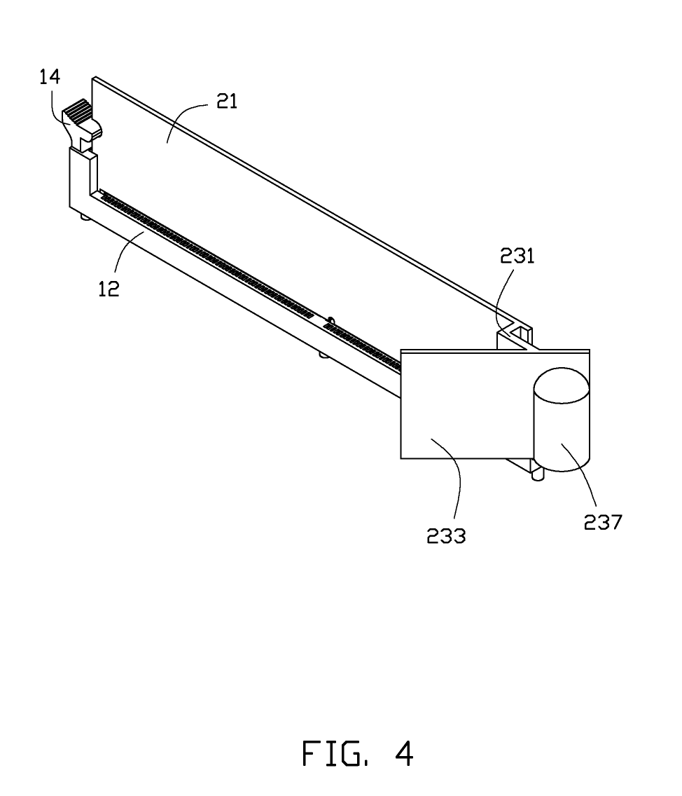

FIGS. 2 to 4 show that in assembly, the latches 14 are rotated away from each other. The feet 214 are inserted into the slot 121. One of the latches 14 is received in the recess 237. Then the latches 14 are rotated towards the main plate 21 and engaged in the notches 212. Thereby, the airflow guide member 20 is mounted to the card socket 10.

The airflow guide member 20 is integrally formed of non-conductive material, such as plastic. Therefore, the airflow guide member 20 is non-electrically connected to the card socket 10.

In use, the card socket 10 is mounted in an electronic device. When the card socket 10 is idle, the airflow guide member 20 is mounted to the idle card socket 10, to allow the airflow guide portion 233 to face airflow. Airflow towards the card socket 10 will be guided by the airflow guide portion 233 away from the card socket 10 to other electronic components beside the card socket 10, to achieve greater heat dissipation of electronic components beside the card socket 10.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. An airflow guide member, comprising:
a main plate made of non-conductive material, and comprising a first end and a second end opposite to the first end, wherein a notch is defined in each of the first end and the second end of the main plate, at least one foot is formed on a bottom of the main plate; and
an airflow guide plate made of non-conductive material and formed on the first end of the main plate, wherein the airflow guide plate comprises an airflow guide portion slanted relative to the main plate.

2. The airflow guide member of claim 1, wherein the airflow guide member is integrally formed.

3. The airflow guide member of claim 2, wherein the airflow guide member is made of plastic.

4. The airflow guide member of claim 1, wherein the airflow guide plate further comprises a connecting portion connected to a first side of the main plate adjacent to the first end, the airflow guide portion is connected to the connecting portion, an acute angel is formed between the airflow guide portion and the first side of the main plate, and an obtuse angel is formed between the airflow guide portion and a second side of the main plate opposite to the first side.

5. The airflow guide member of claim 4, wherein the connecting portion is substantially L-shaped, and comprises a first plate connected to the first side of the main plate in a substantially perpendicular manner, and a second plate extending from a distal end of the first plate in a substantially perpendicular manner, a distal end of the second plate extends out of the first end of the main plate, and a middle of a side of the airflow guide portion is connected to the distal end of the second plate.

6. The airflow guide member of claim 5, wherein an arc-shaped recess is defined in a section of a side of the airflow guide portion facing the second side of the main plate.

7. The airflow guide member of claim 1, wherein the number of the at least one foot is two, and the two feet extend down from opposite ends of the bottom of the main plate.

8. A card socket assembly, comprising:
a card socket comprising a main body defining a slot in a top of the main body, and two latches rotatably connected to opposite ends of the main body; and
a non-conductive airflow guide member comprising a main plate and an airflow guide plate formed on a first end of the main plate, wherein a bottom of the main plate is inserted into the slot of the card socket, two notches are defined in the first end and a second end of the main plate opposite to the first end, to receive the latches, the airflow guide plate comprises an airflow guide portion slanted relative to the main plate, to guide airflow away from the card socket.

9. The card socket assembly of claim 8, wherein the airflow guide member is integrally formed.

10. The card socket assembly of claim 9, wherein the airflow guide member is made of plastic.

11. The card socket assembly of claim 8, wherein the airflow guide plate further comprises a connecting portion connected to a first side of the main plate adjacent to the first end, the airflow guide portion is connected to the connecting portion, an acute angel is formed between the airflow guide portion and the first side of the main plate, and an obtuse angel is formed between the airflow guide portion and a second side of the main plate opposite to the first side.

12. The card socket assembly of claim 11, wherein the connecting portion is substantially L-shaped, and comprises a first plate connected to the first side of the main plate in a substantially perpendicular manner, and a second plate extending from a distal end of the first plate in a substantially perpendicular manner, a distal end of the second plate extends out of the first end of the main plate, and a middle of a side of the airflow guide portion is connected to the distal end of the second plate.

13. The card socket assembly of claim 12, wherein an arc-shaped recess is defined in a section of a side of the airflow guide portion facing the second side of the main plate, when the latches rotate away from the main plate, one of the latches is received in the recess.

14. The card socket assembly of claim 8, wherein two feet extend down from the bottom of the main plate, to be inserted into the slot of the card socket.
